(19) United States
(12) Patent Application Publication
(10) Pub. No.: US 2021/0070995 A1
(43) Pub. Date: Mar. 11, 2021

(54) CRYSTALLINE POLYAMIDE RESIN COMPOSITION FOR IC TRAY

(71) Applicant: KOREA ENGINEERING PLASTICS CO., LTD., Seoul (KR)

(72) Inventors: Bong Joo PARK, Goyang-si (KR); Soon Young CHA, Uiwang-si (KR); Si Jun PARK, Seoul (KR)

(21) Appl. No.: 17/011,484

(22) Filed: Sep. 3, 2020

(30) Foreign Application Priority Data
Sep. 6, 2019 (KR) 10-2019-0110413

(51) Int. Cl. C08L 77/06

(52) U.S. Cl. CPC C08L 77/06; C08L 2205/025; C08L 2205/035

(57) ABSTRACT

Provided is polyamide resin composition for an integrated circuit tray. A novel polyamide resin composition for an integrated circuit tray, which does not cause deformation due to its crystallization and has a short solidification time, is also provided. A polyamide resin composition can include a polyamide-based matrix resin, an amorphous polyamide resin, a crystalline polyphthalamide resin, carbon fibers, and glass fibers, wherein the polyamide-based matrix resin is selected from nylon 6, nylon 66, or a mixture thereof.

### CROSS-REFERENCE TO RELATED APPLICATIONS

This application claims priority under 35 U.S.C. § 119 to Korean Patent Application No. 10-2019-0110413, filed on Sep. 6, 2019, in the Korean Intellectual Property Office, the disclosure of which is incorporated herein by reference in its entirety.

### TECHNICAL FIELD

The following disclosure relates to a polyamide resin composition for an integrated circuit tray.

Also, the present disclosure provides a novel polyamide resin composition for an integrated circuit tray, which is not cause deformation due to its crystallization and has a short solidification time.

### BACKGROUND

An integrated circuit tray (an IC tray) is also referred to as a semiconductor tray. The IC tray is a container that accommodates semiconductors. In this case, the semiconductors are transferred while being loaded on the IC tray during the semiconductor production and are often exposed to various chemicals such as semiconductor materials in processes such as exposure to heat at 140° C. or higher and treatment with photosensitizers during the transfer process. Also, even after the semiconductor production process is completed, the IC tray is used as protection and packaging materials or carrier materials for semiconductors. Therefore, the IC tray serves to protect the semiconductors even when it is exposed to various surrounding environments, for example, various environments such as a change in temperature, humidity, electrical stimuli, and the like.

Accordingly, a resin composition constituting the integrated circuit tray may need to be less deformed so that it does not cause physical, chemical, and electrical damages to the semiconductors in environments in which there are compounds, a temperature, humidity, and electrical stimuli while semiconductors are being produced or after the production of the semiconductors is completed or after the semiconductor packaging is completed, and it also requires electrical characteristics, such as electrical conductivity, sufficient to exert the antistatic functions.

Also, the integrated circuit tray should not be deformed by heat, but may be deformed depending on a degree of crystallization when it is manufactured by injection. Therefore, there is a need for a novel resin composition capable of preventing the deformation.

In addition, as the semiconductors are reduced in size with the recent advance in the degree of integration of the semiconductors, a pocket (a part into which a semiconductor is loaded) of the IC tray also has a more complicated structure, and becomes thinner for microformation. Therefore, the integrated circuit tray also requires high flow characteristics. If the resin composition used to manufacture the integrated circuit tray does not meet the high flow characteristics and resistance to deformation of molded articles manufactured using the resin composition as the same time, the IC tray has poor surface uniformity, and thus dust may form due to the tray-to-tray friction, resulting in defective semiconductors when the IC tray is manufactured from the resin composition.

### RELATED ART DOCUMENT

### Patent Document

Patent Document 1: Korean Patent Publication No. 10-0867986 (Nov. 4, 2008)

The disclosure of this section is to provide background information relating to the invention. Applicant does not admit that any information contained in this section constitutes prior art.

### SUMMARY

An embodiment of the present invention is directed to providing a novel resin composition for an integrated circuit tray.

Another embodiment of the present invention is directed to providing a resin composition which has excellent moldability while showing conductivity and is capable of maintaining dimensional stability before and after the resin composition is subjected to a cooling process after injection or extrusion and is continuously exposed to high-temperature environment.

Still another embodiment of the present invention is directed to providing a novel polyamide resin composition in which there is no dust formation due to the tray-to-tray friction because processed trays have a uniform surface.

The present inventors have conducted extensive research, and found that, when an integrated circuit tray is manufactured using a polyamide resin composition, which includes a polyamide-based matrix resin (selected from nylon 6, nylon 66, or a mixture thereof), an amorphous polyamide resin, a crystalline polyphthalamide resin, carbon fibers, and glass fibers, defects of the integrated circuit tray may be minimized or reduced. Therefore, embodiments of the present invention has been completed based on these facts.

In a general aspect, a polyamide resin composition, which includes 1 to 40 parts by weight of an amorphous polyamide resin, 1 to 40 parts by weight of a crystalline polyphthalamide resin, 5 to 30 parts by weight of carbon fibers, and 5 to 150 parts by weight of glass fibers, based on 100 parts by weight of the matrix resin, is provided.

In a general aspect of the present invention, the amorphous polyamide resin may include any one or two or more mixed components selected from 6I/6T, 6/6T, 6/6I, 6/3/T, 6I, 4I, 4T, or polyamide 12/MACMI whose crystallization is reduced in a semicrystalline polymer.

In a general aspect of the present invention, the composition may also be a polyamide resin composition having a tensile strength of 150 MPa or more, a flexural strength of 230 MPa or more, a flexural modulus of 9,000 MPa or more, and an impact strength of 7 kJ/m² or more.

In a general aspect of the present invention, when the resin composition, which has a warpage A1+A2 of 10 or less, as measured after an injection-molded specimen with 230 mm×150 mm×1.8 mm is controlled to be maintained at a temperature of 23±2° C. and a relative humidity of 50±5% for 24 hours, is provided, the formation of dust caused by the tray-to-tray friction may be minimized, thereby minimizing defective semiconductors.

In another general aspect, a polyamide resin composition is provided, which includes a polyamide-based matrix resin, an amorphous polyamide resin, a crystalline polyphthalamide resin, and a conductive agent, wherein the polyamide-based matrix resin is selected from nylon 6, nylon 66, or a mixture thereof, and wherein the composition is a polyamide resin composition that has a tensile strength of 150 MPa or more, a flexural strength of 230 MPa or more, a flexural modulus of 9,000 MPa or more, and an impact strength of 7 kJ/m² or more, and has a warpage A1+A2 of 10 or less, as measured after an injection-molded specimen with 230 mm×150 mm×1.8 mm is controlled to be maintained at a temperature of 23±2° C. and a relative humidity of 50±5% for 24 hours.

In the polyamide composition according to general aspects of the present invention, the resin composition may be a polyamide resin composition having a surface roughness of 0.3 or less.

In still another general aspect, an integrated circuit tray manufactured from the compositions is provided.

### BRIEF DESCRIPTION OF THE DRAWINGS

The above and other aspects, features and advantages of the present invention will become more apparent to those of ordinary skill in the art by describing in detail embodiments thereof with reference to the attached drawings, in which:

FIGS. 1 and 2 show a method of measuring a warpage distance according to the present invention.

### DETAILED DESCRIPTION OF EMBODIMENTS

Hereinafter, embodiments of the present invention will be described in further detail with reference to embodiments and examples thereof, which include the accompanying drawings. However, it should be understood that the following embodiments or examples are only illustrative to describe the present invention in detail, and the present invention is not limited thereto and may be implemented in various forms.

Also, unless defined otherwise, all technical and scientific terms used herein have the same meanings as commonly understood by one skilled in the art to which the present disclosure pertains. Terms used for description in the present disclosure are intended to effectively describe particular embodiments, but are not intended to limit the present invention.

In addition, singular forms used in the specification and the appended claims are intended to include plural forms as well, unless otherwise specified in the context.

Further, a certain part “including” a certain element signifies that the certain part may be further inclusive, instead of exclusive, of another element unless particularly indicated otherwise.

In one implementation, the resin compositions including an amorphous resin such as a modified polyphenylene oxide (mPPO) or a modified polyphenylene ether (mPPE) have been mainly used to prevent thermal deformation or deformation caused by crystallization. However, in case of the mPPO resin and the mPPE resin, dust may form due to the tray-to-tray friction because they show poor moldability due to low flowability during the injection, and have a non-uniform surface.

Further, polyamide (PA) that is a crystalline resin can be used, but is difficult to apply to the IC tray because the crystalline polyamide may be deformed or changed in dimension due to the crystallization during a cooling process after the injection. Also, the polyamide (PA) may often be deformed during a cooling process after it is subjected to heat treatment at a temperature higher than the glass transition temperature (Tg) during the semiconductor production process. Also, because the polyamide (PA) has poor dispersibility with CF or GF for improvement of electrical conductivity and strength, it has a deformed surface or poor smoothness, and thus dust may form due to the friction between trays, resulting in defective semiconductors.

Meanwhile, when the amorphous polyamide is used, it is difficult to eject it from a mold due to an increase in solidification time, and it may be deformed after heat treatment at a temperature higher than the Tg and cooling in the semiconductor process.

Hereinafter, embodiments of the present invention will be described in detail.

Embodiments of the present invention relate to a novel polyamide resin composition for an integrated circuit tray, which has improved productivity and electrical characteristics and shows no dust formation when the resin composition is applied for an integrated circuit tray because defects as changes in dimensions and shapes caused by crystallization and high-temperature exposure may be minimized or reduced by binding a polyamide-based resin serving as a matrix resin to an amorphous amide and a crystalline phthalamide.

For this purpose, embodiments of the present invention relate to a polyamide resin composition for an integrated circuit tray, which is manufactured using a polyamide-based resin selected from nylon 6, nylon 66, or a mixture thereof as the matrix resin, wherein the polyamide resin composition includes an amorphous polyamide resin, a crystalline polyphthalamide resin, and a conductive agent.

In embodiments of the present invention, when the composition including the components is applied, the surface becomes smooth, and a decline in economic feasibility as an injection cycle time increases with a solidification time during use of the amorphous resin may be minimized or significantly reduced.

Also, when an injection cooling time is set to be short in order to enhance productivity, the defects such as bending or attachment of the IC tray to a mold during ejection, and a non-uniform surface of the IC tray caused due to a change in shape may also be minimized or significantly reduced.

Therefore, embodiments of the present invention provide a novel composition capable of reducing a solidification time and lowering the formation of dust (particles) due to the uniform surface at the same time (desirably in a solidification time of 7 seconds), as described above.

In embodiments of the present invention, when polyamide 6 is used as the matrix resin, the matrix resin desirably has a relative viscosity (R.V) of 2.60±0.5. This is because polyamide 6 has excellent injection characteristics, and may be melted together when it is mixed with polyamide 66, shows excellent miscibility, and retains the injection characteristics. When polyamide 6 is used alone, the present invention is not limited thereto. Also, polyamide 66 of embodiments of the present invention is a resin having excellent mechanical rigidity and heat resistance. Non-limiting examples of polyamide 66 desirably include resins having an R.V (sulfuric acid, at 25° C.) of 2.4±0.5 and a weight average molecular weight of 11,000 to 21,000 g/mol, but the present invention is not limited thereto.

Also, in embodiments of the present invention, an amorphous polyamide component may be bound to other components to increase surface hardness and reduce a shrinkage rate, and may reduce the formation of dust and particles by friction because the surface becomes smooth after processes such as injection, and the like. Non-limiting examples of the amorphous polyamide component include polyamides having an R.V (sulfuric acid, at 25° C.) of 1.9±0.5, but the present invention is not limited thereto.

In embodiments of the present invention, the amorphous polyamide resin is not particularly limited as long as it is an amorphous polyamide resin. For example, examples of the amorphous polyamide resin include amorphous polyphthalamides 6I/6T, 6/6T, 6/6I, 6/3/T, 6I, 4I, 4T, or a polyamide 12/MACMI whose crystallization is reduced in a semicrystalline polymer, but the present invention is not limited thereto.

Next, the crystalline polyphthalamide resin will be described. A crystalline polyphthalamide is bound to the matrix resin and the amorphous polyamide to improve the heat resistance of a composition, and may also serve to improve dimensional stability of the integrated circuit tray. Interestingly, the crystalline polyphthalamide may have an unexpected effect of shortening a solidification time in the composition containing such a component. By way of example, the crystalline polyphthalamide is desirably a resin having a relative viscosity (R.V) (sulfuric acid, at 25° C.) of 2.0±0.5, but the present invention is not limited thereto.

In one example of the present invention, a polyamide resin composition is provided, which includes 1 to 40 parts by weight of the amorphous polyamide resin, 1 to 40 parts by weight of the crystalline polyphthalamide resin, 5 to 30 parts by weight of the carbon fibers, and 5 to 150 parts by weight of the glass fibers, based on 100 parts by weight of the polyamide-based resin selected from nylon 6, nylon 66, or a mixture thereof as the matrix resin. However, this composition is advantageous to achieve the physical properties of embodiments of the present invention, but is not limited to a composition ratio thereof.

When the composition ratio is used, the polyamide resin composition is advantageous because it may increase surface hardness, reduce a shrinkage rate, improve surface uniformity, and enhance an injection property while retaining excellent heat resistance and rigidity.

In embodiments of the present invention, the carbon fibers and the glass fibers are not particularly limited, but carbon fibers and glass fibers having a diameter of 5 to 10 μm and a length of 4 to 8 mm may, for example, be used, but the present invention is not limited thereto. Also, the surface electrical conductivity may be improved to prevent damage of semiconductor caused by static electricity in a semiconductor process or contamination of foreign substances.

Also, in embodiments of the present invention, the composition may be a polyamide resin composition having a tensile strength of 150 MPa or more, a flexural strength of 230 MPa or more, a flexural modulus of 9,000 MPa or more, and an impact strength of 7 kJ/m² or more.

In addition, in embodiments of the present invention, when the resin composition, which has a warpage A1+A2 of 10 or less, as measured after an injection-molded specimen with 230 mm×150 mm×1.8 mm is controlled to be maintained at a temperature of 23±2° C. and a relative humidity of 50±5% for 24 hours, is provided, the formation of dust caused by the tray-to-tray friction may be minimized, thereby minimizing defective semiconductors.

Further, embodiments of the present invention provide a polyamide resin composition including a polyamide-based matrix resin, an amorphous polyamide resin, a crystalline polyphthalamide resin, and a conductive agent, wherein the polyamide-based matrix resin is selected from nylon 6, nylon 66, or a mixture thereof, and wherein the composition may be a polyamide resin composition that has a tensile strength of 150 MPa or more, a flexural strength of 230 MPa or more, a flexural modulus of 9,000 MPa or more, and an impact strength of 7 kJ/m² or more, and has a warpage A1+A2 of 10 or less, as measured after an injection-molded specimen with 230 mm×150 mm×1.8 mm is controlled to be maintained at a temperature of 23±2° C. and a relative humidity of 50±5% for 24 hours.

Also, in one example of the present invention, the composition may further include a pigment.

In addition, in one example of the present invention, the composition may further include one or more additive selected from an antioxidant, a heat-resistant additive, a lubricant, and the like.

In embodiments of the present invention, the antioxidant and the lubricant may be used at 0.05 to 3 parts by weight, based on 100 parts by weight of the matrix resin, the amorphous polyamide resin, and the crystalline polyphthalamide resin. IN embodiments, the antioxidant and the lubricant are used at 0.1 to 1 parts by weight because they do not cause damage to other physical properties, but the present invention is not limited thereto.

Hereinafter, embodiments of the present invention will be described in detail with reference to examples thereof, which include the accompanying drawings. Therefore, it will be apparent that the present invention is not limited to the following examples, and may be implemented in various forms without departing from the scope of the present invention.

### Examples 1 to 4 and Comparative Examples 1 and 2

A low-viscosity polyamide 6 resin (PA6 Hyosung 1011BRT) having a relative viscosity of 2.6, a low-viscosity polyamide 66 resin (PA66 Solvay 24AE1) having a relative viscosity of 2.4, a crystalline polyphthalamide resin (Crystalline PPA Ebonics M1100), an amorphous polyamide resin (EMS TR90), carbon fibers (SunYoung SYC-TR-PU6), glass fibers (KCC GF311), a lubricant (calcium stearate; Songwon Industrial SC130), an antioxidant (IRG1098 BASF), and carbon black (Joyang MB9002L) were adjusted in contents listed in Table 1 below, and then blended for 20 minutes for a ribbon-type mixing machine. Thereafter, the resulting mixture was put into a twin-screw extruder, and then sufficiently melt-mixed at 250° C.

This mixture was discharged in the form of a strand via a die, sufficiently cooled in a cooling bath, and cut into chips using a pelletizer.

The materials were sufficiently dried at 80° C. in an oven, and molded articles were manufactured using the materials by subjecting a specimen for measuring physical properties to injection molding at 250° C., and the physical properties were measured. The results are listed in Tables 2 to 4.

TABLE 1

| | Examples | | | | Comparative Examples | |
|---|---|---|---|---|---|---|
| | (% by weight) | | | | (% by weight) | |
| Articles | 1 | 2 | 3 | 4 | 1 | 2 |
| PA6 | 18.6 | 36.6 | 36.6 | 26.6 | 18.6 | 18.6 |
| PA66 | 20.0 | 40.0 | 40.0 | 30.0 | 20.0 | 20 |
| C-PPA | 5 | 10 | 2 | 2 | 0 | 10 |
| Amorphous amide | 5 | 2 | 10 | 10 | 10 | 0 |
| Carbon Fibers | 10 | 5 | 5 | 10 | 10 | 20 |
| Glass Fibers | 40 | 5 | 5 | 20 | 40 | 30 |
| Lubricant | 0.2 | 0.2 | 0.2 | 0.2 | 0.2 | 0.2 |
| Antioxidant | 0.2 | 0.2 | 0.2 | 0.2 | 0.2 | 0.2 |
| Carbon Black | 1 | 1 | 1 | 1 | 1 | 1 |

Table 2 below is a table listing values obtained by measuring the tensile strength, the tensile elongation, the flexural strength, the flexural modulus, and the impact strength. The tensile strength was measured according to ISO 527, the flexural strength and the flexural modulus were measured according to ISO 178, and the impact strength (Charpy notched) was measured according to ISO179/1eA.

As a result, it was revealed that all Examples 1 to 4 according to embodiments of the present invention showed significantly enhanced mechanical properties, as listed in Table 2 below. However, when an integrated circuit tray did not have the composition of embodiments of the present invention, it showed very inferior physical properties.

TABLE 2

| | Tensile | Tensile | Flexural | Flexural | Impact |
|---|---|---|---|---|---|
| | strength | elongation | strength | modulus | strength |
| Items | (MPa) | (%) | (MPa) | (MPa) | (kJ/m²) |
| Example 1 | 263 | 0.4 | 286 | 17,830 | 16.8 |
| Example 2 | 192 | 2.9 | 265 | 11,460 | 9.4 |
| Example 3 | 176 | 2.9 | 244 | 9,880 | 8.9 |
| Example 4 | 215 | 2.3 | 317 | 14,320 | 10.8 |
| Comparative | 212 | 2.1 | 310 | 14,210 | 15.7 |
| Example 1 | | | | | |
| Comparative | 306 | 0.2 | 366 | 20,340 | 16.4 |
| Example 2 | | | | | |

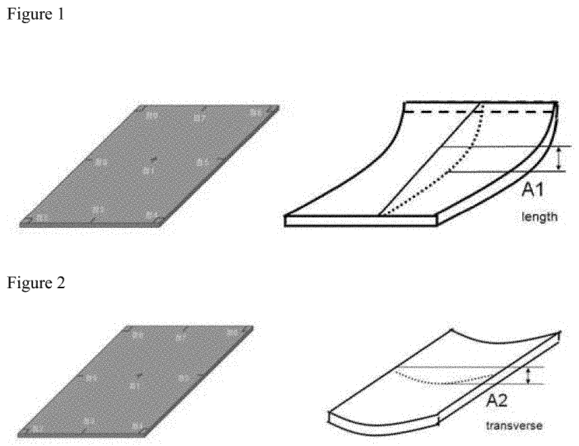

Table 3 below is a table listing values obtained by measuring the warpage using the following method. The warpage refers to a phenomenon in which a molded article is twisted due to the orientation of molecules or the partial deviation of the shrinkage rate caused by a difference in solidification rate, and is measured using the following method.
Measuring facility: non-contact dimension measuring meter (Maker/MODEL: MICROVU/M3010181)
Measurement condition: measured after an injection-molded specimen with 230 mm×150 mm×1.8 mm is controlled to be maintained at a temperature of 23±2° C. and a relative humidity of 50±5% for 24 hours
Measurement method: as shown in FIG. 1, a central dot of nine dots in a specimen is originally calibrated, coordinates (x,y,z) of the remaining eight dots are measured, and a deflection is calculated using the measured coordinates. Then, as shown in FIG. 1, a warpage distance A1 is calculated using dots 1, 3, 7, and A2 is calculated using dots 9, 1, and 5, as shown in FIG. 2.

As a result, as listed in Table 3, the warpage was observed to be less than 5 mm in each direction in examples of the present invention, and the warpage of 7 mm or more was not observed in all Comparative Examples. Therefore, it can be seen that, when a thinner integrated circuit tray was manufactured, the integrated circuit trays of Comparative Examples would show a very low warpage, but had a very high warpage in the case of embodiments of the present invention.

Also, for the solidification time measured as the minimal time in which a poor mold release is not caused while adjusting a cooling time of an injection machine at a unit of 0.1 second under the same injection conditions capable of minimizing the deformation after injection, the IC tray was possibly solidified for a time period of less than 8 seconds in the case of embodiments of the present invention, but the IC tray was not solidified or solidified for a long period of time in the case of Comparative Example 1. Also, as listed in Table 4, the IC tray had very poor surface roughness due to the poor mold release, and it is difficult to use the IC tray because the IC tray had a good solidification rate but showed very poor surface roughness in the case of Comparative Example 2.

TABLE 3

| Items | A1 | A2 | A1 + A2 | Solidification time (s) |
|---|---|---|---|---|
| Example 1 | 3.8 | 3.6 | 7.4 | 6.5 |
| Example 2 | 4.3 | 4.1 | 8.4 | 7.9 |
| Example 3 | 4.1 | 4.0 | 8.1 | 7.9 |
| Example 4 | 3.9 | 3.8 | 7.7 | 7.2 |
| Comparative Example 1 | — | — | — | Poorly released due to |
| | | | | insufficient solidification |
| Comparative Example 2 | 8.2 | 8.0 | 16.2 | 6.4 |

Table 4 lists the surface roughness measured for specimens used in measuring the warpage using a surface roughness measuring machine (TOKYOSEIMITSU, Surfcom 574A). As a result, the specimens had very poor surface roughness in the case of Comparative Examples. Therefore, it can be expected that dust formed due to the surface friction when the specimens were manufactured for an integrated circuit tray.

TABLE 4

| Items | Surface roughness |
|---|---|
| Example 1 | 0.28 |
| Example 2 | 0.23 |
| Example 3 | 0.21 |
| Example 4 | 0.24 |
| Comparative Example 1 | Poorly released |
| Comparative Example 2 | 0.39 |

The resin composition for an IC tray according to one aspect of the present invention has an advantage in that it has electrical conductivity, and shows excellent mechanical properties (including dimensional stability, heat resistance, and chemical resistance) and durability even when continuously exposed to the high temperature and chemicals.

Also, the resin composition for an IC tray according to one aspect of the present invention has an advantage in that it has a uniform surface, thereby reducing the formation of dust.

In addition, the resin composition for an IC tray according to one aspect of the present invention has characteristics such as a short solidification time and excellent mold releasability after processing.

Further, the resin composition for an IC tray according to one aspect of the present invention may be used to shorten a solidification time and simultaneously reduce the formation of dust due to the uniform surface thereof.

Although embodiments of the invention have been described above, those skilled in the art may understand that configurations of the various embodiments described above may be changed without departing from the spirit of the invention. It will be also understood that the changes fall within the scope of the invention.

What is claimed is:

1. A polyamide resin composition comprising a polyamide-based matrix resin, an amorphous polyamide resin, a crystalline polyphthalamide resin, carbon fibers, and glass fibers, wherein the polyamide-based matrix resin is selected from nylon 6, nylon 66, or a mixture thereof.

2. The polyamide resin composition of claim 1, wherein the polyamide resin composition comprises 1 to 40 parts by weight of the amorphous polyamide resin, 1 to 40 parts by weight of the crystalline polyphthalamide resin, and 5 to 30 parts by weight of the carbon fibers, and 5 to 150 parts by weight of the glass fibers, based on 100 parts by weight of the matrix resin.

3. The polyamide resin composition of claim 1, wherein the amorphous polyamide resin comprises any one or two or more mixed components selected from 6I/6T, 6/6T, 6/6I, 6/3/T, 6I, 4I, 4T, or polyamide 12/MACMI whose crystallization is reduced in a semicrystalline polymer.

4. The polyamide resin composition of claim 1, wherein the resin composition has a tensile strength of 150 MPa or more, a flexural strength of 230 MPa or more, a flexural modulus of 9,000 MPa or more, and an impact strength of 7 kJ/m² or more.

5. The polyamide resin composition of claim 1, wherein the resin composition has a warpage A1+A2 of 10 or less, as measured after an injection-molded specimen with 230 mm×150 mm×1.8 mm is controlled to maintained at a temperature of 23±2° C. and a relative humidity of 50±5% for 24 hours.

6. The polyamide resin composition of claim 1, wherein the resin composition has a surface roughness of 0.3 or less.

7. A polyamide resin composition comprising a polyamide-based matrix resin, an amorphous polyamide resin, a crystalline polyphthalamide resin, carbon fibers, and glass fibers, wherein the polyamide-based matrix resin is selected from nylon 6, nylon 66, or a mixture thereof, and wherein the composition has a tensile strength of 150 MPa or more, a flexural strength of 230 MPa or more, a flexural modulus of 9,000 MPa or more, and an impact strength of 7 kJ/m² or more, and has a warpage A1+A2 of 10 or less, as measured after an injection-molded specimen with 230 mm×150 mm×1.8 mm is controlled to be maintained at a temperature of 23±2° C. and a relative humidity of 50±5% for 24 hours.

8. The polyamide resin composition of claim 7, wherein the amorphous polyamide resin comprises any one or two or more mixed components selected from 6I/6T, 6/6T, 6/6I, 6/3/T, 6I, 4I, 4T, or polyamide 12/MACMI whose crystallization is reduced in a semicrystalline polymer.

9. The polyamide resin composition of claim 7, wherein the resin composition has a surface roughness of 0.3 or less.

10. An integrated circuit tray manufactured from the composition defined in claim 1.

11. An integrated circuit tray manufactured from the composition defined in claim 7.
